(19) United States
(12) Patent Application Publication
(10) Pub. No.: US 2023/0361212 A1
(43) Pub. Date: Nov. 9, 2023

(54) DYNAMIC PERFORMANCE OF ON-CHIP CURRENT SENSORS

(71) Applicant: Wolfspeed, Inc., Durham, NC (US)

(72) Inventors: Madankumar Sampath, Morrisville, NC (US); Sei-Hyung Ryu, Cary, NC (US); Edward Robert Van Brunt, Raleigh, NC (US)

(21) Appl. No.: 17/736,720

(22) Filed: May 4, 2022

(51) Int. Cl. H01L 29/78; H01L 29/423; H01L 29/06; H01L 29/66

(52) U.S. Cl. CPC H01L 29/7815; H01L 29/42368; H01L 29/0696; H01L 29/66712

(57) ABSTRACT

A semiconductor device includes a device region and an on-chip sensor region, such as an on-chip current sensor region. The semiconductor device further includes a transition region formed between the device region and the sensor region. A gate contact extends across the transition region. A conductive segment may be formed on the gate contact in the transition region to reduce a resistivity of the material used to form the gate contact. Additionally or alternatively, an isolation region may be formed under the gate contact between a first isolated well region in the device region and a second isolated well region in the sensor region. The isolation region isolates the first isolated well region from the second isolated well region to prevent current in the device region from propagating into the sensor region.

### FIELD OF THE DISCLOSURE

The present disclosure relates to semiconductor devices, and in particular to semiconductor devices with on-chip current sensors.

### BACKGROUND

Semiconductor devices are ubiquitous in modern electronic devices. Wide bandgap semiconductor material systems, such as gallium nitride (GaN) and silicon carbide (SiC), are increasingly utilized in semiconductor devices to push the boundaries of device performance in areas such as switching speed, power handling capability, and thermal conductivity. Examples include individual devices such as metal-oxide-semiconductor field-effect transistors (MOSFETs), insulated gate bipolar transistors (IGBTs), Schottky barrier diodes, PiN diodes, high electron mobility transistors (HEMTs), and integrated circuits such as monolithic microwave integrated circuits (MMICs) that include one or more individual devices.

Current sensing in semiconductor devices for power switching applications is a way to monitor operating load currents to detect possible failure mechanisms like overcurrent or short-circuit events. In the example of a MOSFET or a metal-insulator-semiconductor field-effect transistor (MISFET), current sensing may be accomplished by providing a separate source contact for a small number of active region unit cells. The separate source contact is arranged to form a separate path for a proportionally small amount of an overall device load current. The amount of the load current along the separate path can be measured and used to calculate the overall load current along the remainder of the semiconductor device. While current sensing arrangements in semiconductor devices have been proposed, the conventional structures may not be suitable for withstanding various adverse operating conditions that may be experienced.

### SUMMARY

The present disclosure is related to semiconductor devices. A semiconductor device may include a device region and a sensor region, for example, a current sensor region that occupies a portion of an overall active area of the semiconductor device. The current sensor region may be configured to monitor device load currents in the device region during operation. The semiconductor device further includes a transition region formed between the device region and the sensor region. A gate contact extends across the transition region. A conductive segment may be formed on the gate contact in the transition region to reduce resistivity of the material used to form the gate contact. Additionally or alternatively, an isolation region may be formed under the gate contact between a first isolated well region in the device region and a second isolated well region in the sensor region. The isolation region isolates the first isolated well region from the second isolated well region to prevent current in the device region from propagating into the sensor region.

In one aspect, a vertical semiconductor device includes a drift region, a device region that comprises a first portion of the drift region, and a sensor region that comprises a second portion of the drift region. A transition region is formed between the device region and the sensor region. The transition region includes a gate contact and a conductive segment on and in direct contact with the gate contact.

In another aspect, a vertical semiconductor device includes a drift region, a device region that comprises a first portion of the drift region, and a sensor region that comprises a second portion of the drift region. A transition region is formed between the device region and the sensor region. The transition region includes a gate contact and an isolation region under the gate contact. In one embodiment, the isolation region is between a first isolated well region in the first portion of the drift region and a second isolated well region in the second portion of the drift region.

In yet another aspect, a vertical semiconductor device includes a drift region, a device region that comprises a first portion of the drift region, and a sensor region that comprises a second portion of the drift region. A transition region is formed between the device region and the sensor region. The transition region includes a gate contact, a conductive segment on and in direct contact with the gate contact, and an isolation region under the gate contact between a first isolated well region in the first portion of the drift region and a second isolated well region in the second portion of the drift region.

In another aspect, a vertical silicon carbide (SiC) device includes a device region and a sensor region. A transition region is between the device region and the sensor region. The vertical SiC device can be operable to detect a short circuit event in less than one microsecond, in one to three microseconds, in one to five microseconds, or in less than ten microseconds.

In yet another aspect, a vertical semiconductor device includes a drift region and a device region that comprises a first portion of the drift region. One or more sensor regions each comprise a second portion of the drift region. Each sensor region includes one or more sensors. Each sensor in a respective sensor region is at an equal distance from a respective gate contact that is electrically connected to the one or more sensors in the respective sensor region.

In other aspects, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a top view layout for an example semiconductor device according to embodiments of the present disclosure;

FIG. 2A illustrates a first equivalent circuit for an implementation of a current sensor for a metal-oxide-semiconductor field-effect transistor (MOSFET) device or metal-insulator-semiconductor field-effect transistor (MISFET) device according to embodiments of the present disclosure;

FIG. 2B illustrates a second equivalent circuit for an implementation of a current sensor for a MOSFET device or a MISFET device according to embodiments of the present disclosure;

FIG. 3 illustrates a cross-sectional view of a portion of a semiconductor device that includes a sensor contact integrated within the semiconductor device;

FIG. 4 illustrates a cross-sectional view of a portion of a first semiconductor device that is similar to the semiconductor device of FIG. 3 and further includes protection structures arranged in a transition region;

FIG. 5 illustrates a top view of a portion of a semiconductor device according to embodiments of the present disclosure;

FIG. 6 illustrates a cross-sectional view of a portion of a second semiconductor device that includes conductive segments formed over gate contacts according to embodiments of the present disclosure;

FIG. 7 illustrates a cross-sectional view of a portion of a third semiconductor device that is similar to the first semiconductor device of FIG. 4 and the second semiconductor device of FIG. 6 and includes an insulating layer that forms a nonplanar shape according to embodiments of the present disclosure;

FIG. 8 illustrates a cross-sectional view of a portion of a fourth semiconductor device that is similar to the first semiconductor device of FIG. 4 and the second semiconductor device of FIG. 6 and includes an insulating layer that is formed to cover a larger portion of a top surface of a drift region according to embodiments of the present disclosure;

FIG. 9 illustrates a cross-sectional view of a portion of a fifth semiconductor device that is similar to the first semiconductor device of FIG. 4 and includes an isolation region positioned between a first isolated well region and a second isolated well region according to embodiments of the present disclosure;

FIG. 10A illustrates a graph of turn on times for a current sensor and a device MOSFET;

FIG. 10B illustrates a graph of turn off times for the current sensor and the device MOSFET;

FIG. 11 illustrates a cross-sectional view of a portion of a sixth semiconductor device that is similar to the fifth semiconductor device of FIG. 9 and that is operable to detect one or more events in one or more device MOSFETs according to embodiments of the present disclosure;

FIG. 12 illustrates a cross-sectional view of a portion of a seventh semiconductor device that is similar to the third semiconductor device of FIG. 7 and the fifth semiconductor device of FIG. 9 and includes the isolation regions and the insulating layer that forms the nonplanar shape according to embodiments of the present disclosure;

FIG. 13 illustrates a cross-sectional view of a portion of an eighth semiconductor device that is similar to the fourth semiconductor device of FIG. 8 and to the fifth semiconductor device of FIG. 9 and includes the isolation regions and the insulating layer that is formed to cover larger portions of the top surface of the drift region according to embodiments of the present disclosure;

FIG. 14 illustrates an example first layout for a sensor region;

FIG. 15 illustrates an example second layout for a sensor region according to embodiments of the disclosure;

FIG. 16 illustrates an example third layout for a sensor region according to embodiments of the disclosure; and

FIG. 17 illustrates an example fourth layout for a first sensor region and a second sensor region according to embodiments of the disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element and similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

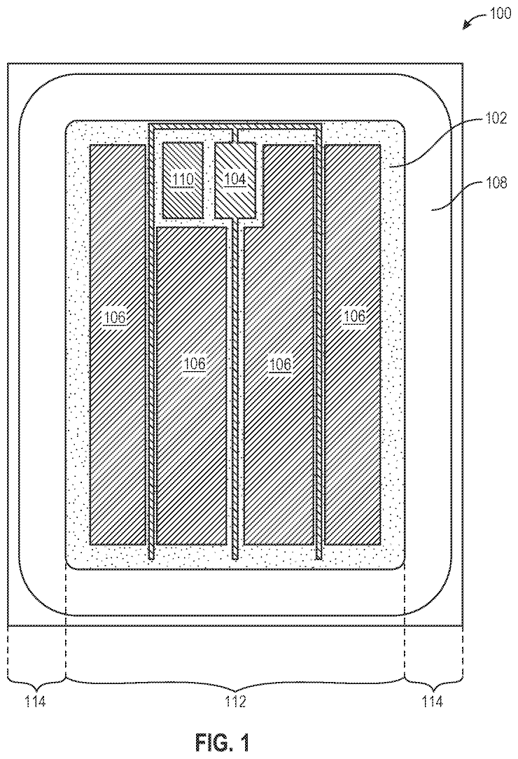

FIG. 1 illustrates a top view layout for an example semiconductor device 100 according to embodiments of the present disclosure. For purposes of illustration, the semiconductor device 100 is a vertical metal-oxide-semiconductor field-effect transistor (MOSFET) device that includes a passivation structure 102 formed with openings for a gate contact 104 and a number of source contacts 106. While a MOSFET is illustrated, the principles of the present disclosure are applicable to other semiconductor devices, for example, other MOSFETs, metal-insulator-field-effect transistors (MISFETs), diodes, Schottky diodes, junction barrier Schottky (JBS) diodes, PiN diodes, and insulated gate bipolar transistors (IGBTs), among others. The semiconductor device 100 may embody wide bandgap semiconductor devices, for example, silicon carbide (SiC)-based devices, and still further 4H-SiC based devices.

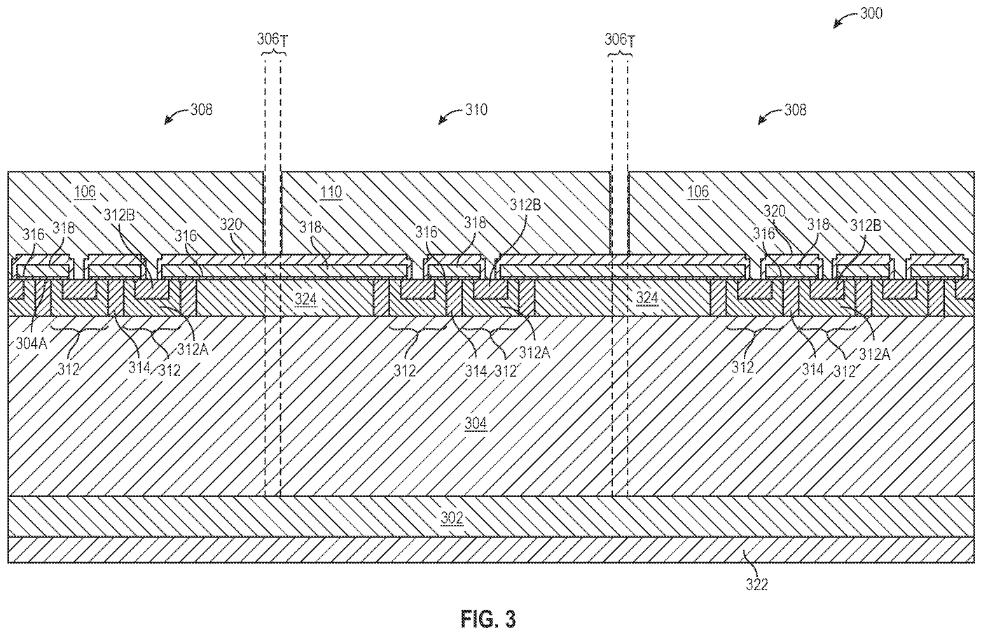

The semiconductor device 100 is a vertical power device in which a drain contact (e.g., drain contact 322 in FIG. 3) is located on a backside of the semiconductor device 100. The gate contact 104 and the source contacts 106 may be provided as surfaces for coupling the semiconductor device 100 to external circuitry.

An edge termination region 108 may be arranged along a perimeter of the semiconductor device 100. The edge termination region 108 may be arranged to reduce a concentration of an electric field at the edges of the semiconductor device 100 in order to improve the performance thereof. For example, the edge termination region 108 may increase a breakdown voltage of the semiconductor device 100 and/or decrease a leakage current of the semiconductor device 100 over time. By way of example, the edge termination region 108 may include one or more guard rings, a junction termination extension (JTE), and combinations thereof.

The semiconductor device 100 may further comprise a sensor contact 110. The sensor contact 110 may provide a contact for any type of sensor that is at least partially incorporated within the semiconductor device 100, for example, a temperature sensor, a strain sensor, or a current sensor. In the case of a current sensor, a current sensor region that corresponds with the sensor contact 110 may occupy an area of the semiconductor device 100 that would otherwise form part of an active region 112 for the semiconductor device 100. In the example of FIG. 1, the edge termination region 108 may serve to delineate the active region 112 of the semiconductor device 100 from an inactive region 114 of the semiconductor device 100, and the sensor contact 110 defines the current sensor region that would otherwise form part of the active region 112. In this regard, the sensor contact 110 may generally have a size that is smaller than a size of the remaining active region 112 of the semiconductor device 100.

The sensor contact 110 provides a contact pad that may be electrically connected, for example, by a wire bond or other electrical connection to one or more external circuit elements for sensor monitoring. In the case of a current sensor, the sensor contact 110 may be electrically connected to one or more external circuit elements for monitoring a portion of the load current that flows in the sensor region of the semiconductor device 100 that is electrically coupled to the sensor contact 110.

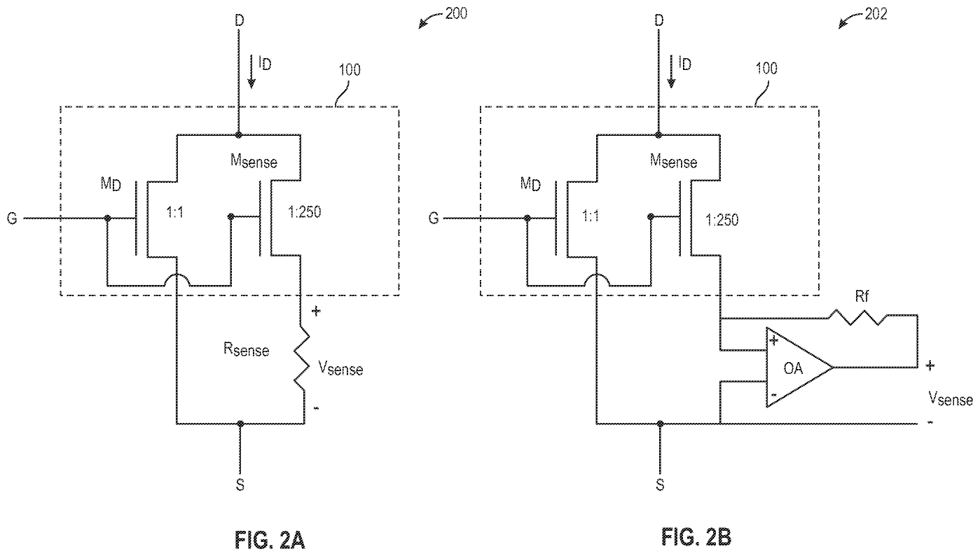

FIG. 2A illustrates a first equivalent circuit 200 for an implementation of a current sensor for a MOSFET device or a MISFET device according to embodiments of the present disclosure. A dashed-line box in FIG. 2A represents the semiconductor device 100 of FIG. 1 with the remaining portion of the first equivalent circuit 200 being external to the semiconductor device 100. By forming the sensor contact (e.g., sensor contact 110 of FIG. 1) as a separate source contact, the semiconductor device 100 thereby includes a device MOSFET (M_{D}) and a sensing MOSFET (Mₛₑₙₛₑ) that are connected to a common drain and a common gate. Source connections for each of the MOSFETs (M_{D} and Mₛₑₙₛₑ) are coupled in parallel so that the current flow from the drain (ID) may be split across the MOSFETs (M_{D} and Mₛₑₙₛₑ). The ratio of current flow from the source of the device MOSFET (M_{D}) to the current flow from the source of the sensing MOSFET (Mₛₑₙₛₑ) corresponds to a ratio of the area of the semiconductor device 100 that is occupied by the active region to the area of the semiconductor device 100 that is occupied by the sensor region.

By way of example, FIG. 2A illustrates an embodiment where the ratio of current flow is set at 1:250 based on the relative areas of the active region and the sensor region. In this manner, when one amp (A) of current flows through the semiconductor device 100, four milliamps (mA) of current will flow from the source path of the sensing MOSFET (Mₛₑₙₛₑ). By arranging the sense resistor (Rₛₑₙₛₑ) along the source path from the sensing MOSFET (Mₛₑₙₛₑ), the corresponding sense voltage (Vₛₑₙₛₑ) may be measured and correlated to the load current of the device MOSFET (M_{D}) according to the ratio described above. Other current sensing configurations are possible with the arrangement of the semiconductor device 100.

For example, FIG. 2B illustrates a second equivalent circuit 202 for an implementation of a current sensor for a MOSFET device or a MISFET device according to embodiments of the present disclosure. The representative second equivalent circuit 202 shows a virtual ground configuration for the portion that is external to the semiconductor device 100. Virtual ground sensing may be used in applications where a higher value of the sense voltage (Vₛₑₙₛₑ) is needed. In this configuration, an operational amplifier (OA) and a feedback resistor (Rf) are coupled to the source path from the sensing MOSFET (Mₛₑₙₛₑ). In this manner, the sense voltage (Vₛₑₙₛₑ) may be calculated based on the feedback resistor (Rf) and an output of the operational amplifier (OA).

In some instances, the type of current sensor corresponds to the type of semiconductor device. For example, the first equivalent circuit 200 depicts a current sensor for a MOSFET device. Accordingly, M_{D} and Mₛₑₙₛₑ are implemented as a device MOSFET (M_{D}) and a sensing MOSFET (Mₛₑₙₛₑ). In other embodiments, M_{D} and Mₛₑₙₛₑ may be implemented with a different type of transistor, where the transistor type correspond to the semiconductor device type.

FIG. 3 illustrates a cross-sectional view of a portion of a semiconductor device 300 that includes the sensor contact 110 of FIG. 1. By way of example, the semiconductor device 300 is arranged as a planar MOSFET, but the principles of the present disclosure are applicable to other semiconductor devices, including trench MOSFETs, MISFETs, diodes, Schottky diodes, JBS diodes, PiN diodes, and IGBTs, among others. The semiconductor device 300 includes a substrate 302 and a drift region 304 over the substrate 302. The drift region 304 may embody one or more drift layers of a wide bandgap semiconductor material, for example, SiC.

The substrate 302 may have a doping concentration between 1×10¹⁷ cm⁻³ and 1×10²⁰ cm⁻³. In various embodiments, the doping concentration of the substrate 302 may be provided at any subrange between 1×10¹⁷ cm⁻³ and 1×10²⁰ cm⁻³. For example, the doping concentration of the substrate 302 may be between 1×10¹⁸ cm⁻³ and 1×10²⁰ cm⁻³, between 1×10¹⁹ cm⁻³ and 1×10²⁰ cm⁻³, between 1×10¹⁷ cm⁻³ and 1×10¹⁹ cm⁻³, between 1×10¹⁷ cm⁻³ and 1×10¹⁸ cm⁻³, and between 1×10¹⁸ cm⁻³ and 1×10¹⁹ cm⁻³.

The drift region 304 may have a doping concentration between 1×10¹⁴ cm⁻³ and 1×10¹⁸ cm⁻³. In various embodiments, the doping concentration of the drift region 304 may be provided at any subrange between 1×10¹⁴ cm⁻³ and 1×10¹⁸ cm⁻³. For example, the doping concentration of the drift region 304 may be between 1×10¹⁵ cm⁻³ and 1×10¹⁸ cm⁻³, between 1×10¹⁶ cm⁻³ and 1×10¹⁸ cm⁻³, between 1×10¹⁷ cm⁻³ and 1×10¹⁸ cm⁻³, between 1×10¹⁴ cm⁻³ and 1×10¹⁷ cm⁻³, between 1×10¹⁴ cm⁻³ and 1×10¹⁶ cm⁻³, between 1×10¹⁴ cm⁻³ and 1×10¹⁶ cm⁻³, between 1×10¹⁵ cm⁻³ and 1×10¹⁷ cm⁻³, between 1×10¹⁵ cm⁻³ and 1×10¹⁶ cm⁻³, and between 1×10¹⁶ cm⁻³ and 1×10¹⁷ cm⁻³.

Vertical dashed lines are provided to indicate one or more transition regions 306_{T} of the semiconductor device 300 that delineate a device region 308 from a sensor region 310. For embodiments with a single integrated sensor contact 110 as illustrated in the top view of FIG. 1, the transition regions 306-r indicated by the dashed lines in FIG. 3 may be a continuous transition region 306-r that surrounds the sensor contact 110. The semiconductor device 300 may include one or more unit cells in both the device region 308 and the sensor region 310. A unit cell refers to a single MOSFET transistor or cell. The device region 308 includes one or more unit cells and the sensor region 310 also includes one or more unit cells. Accordingly, a semiconductor device (e.g., a MOSFET device) includes multiple unit cells. In a non-limiting example, the sensor region 310 includes one or more current sensors.

In FIG. 3, the device region 308 and the sensor region 310 include a pair of junction implants 312 that are provided in the drift region 304, and specifically at a top surface 304A of the drift region 304 opposite the substrate 302 (e.g., in an upper region of the drift region 304 near or adjacent to the top surface 304A). The junction implants 312 include a well region 312A having a doping type that is opposite that of the drift region 304 and a source region 3128 having a doping type that is the same as that of the drift region 304 and in some embodiments, a higher doping concentration than that of the drift region 304. The junction implants 312 may be separated from one another by a junction field-effect transistor (JFET) region 314. The JFET region 314 has the same doping type as that of the drift region 304 and in some embodiments, a higher doping concentration than that of the drift region 304.

A number of the source contacts 106 are provided over the junction implants 312 on the top surface 304A of the drift region 304 in the device region 308 such that each source contact 106 contacts a portion of the well region 312A and the source region 3128. In a similar manner, the sensor contact 110 is provided over the junction implants 312 on the top surface 304A of the drift region 304 in the sensor region 310 such that each sensor contact 110 contacts a portion of the corresponding well region 312A and the source region 3128. In this regard, the sensor contact 110 may form a separate source contact for the sensor region 310. In certain embodiments, the drift region 304 may comprise n− type doping, the source region 3128 may comprise n+ type doping while the well region 312A comprises p-type doping, although reverse polarity configurations are also applicable to the present disclosure.

A gate insulating layer 316, or gate oxide layer depending on the device type, is provided on the top surface 304A of the drift region 304 over the JFET regions 314 and a portion of each one of the junction implants 312 such that the gate insulating layer 316 partially overlaps each one of the source regions 3128. The gate insulating layer 316 may comprise a thin layer of silicon dioxide in certain embodiments, for example, MOSFET configurations where the gate insulating layer 316 may be referred to as a gate oxide layer. In other embodiments, the gate insulating layer 316 may comprise any insulating material, including non-oxide insulating materials and other oxide materials beyond silicon dioxide.

A gate contact 318 is provided on the gate insulating layer 316. As illustrated, the gate contact 318 and the gate insulating layer 316 may be provided for the unit cells in the device region 308, the sensor region 310, and across the transition region 306_{T}. The gate contact 318 for each of the unit cells in both the device region 308 and the sensor region 310 may be coupled to the same gate contact 104 of FIG. 1. In alternative configurations, the semiconductor device 300 may embody a trench MOSFET where portions of the gate contact 318 and the gate insulating layer 316 may reside in a trench of the drift region 304 without deviating from the principles of the present disclosure.

A passivation layer 320 is provided over the gate contact 318 to provide electrical insulation with the source contact 106 and the sensor contact 110. In certain embodiments, the passivation layer 320 may comprise one or more dielectric layers that are referred to as inter-metal dielectrics. The unit cells may be tiled across the device region 308 and the sensor region 310 or tiled in a desired pattern with one or more other semiconductor devices (e.g., diodes) to provide a desired functionality.

A drain contact 322 is provided on a surface of the substrate 302 opposite the drift region 304. Accordingly, the portion of the drift region 304 and corresponding unit cell(s) that are arranged in the device region 308 are electrically connected between the drain contact 322 and the source contact 106. In a similar manner, the portion of the drift region 304 and corresponding unit cell(s) that are arranged in the sensor region 310 are electrically connected between the drain contact 322 and the sensor contact 110. While only a small number of unit cells are illustrated, a ratio of a number of unit cells in the sensor region 310 to a number of unit cells in the device region 308 may be on the order of 1:1, or 1:100, or 1:250, or 1:1,000,000 depending on the desired current ratios for the sensor region 310. In certain embodiments, the sensor region 310 may be arranged to occupy no more than twenty percent (20%), or no more than ten percent (10%), or no more than five percent (5%) of usable active area of the semiconductor device 300 that is within the edge termination region. For current sensing applications, the sensor region 310 may be referred to as a current sensor region.

A doped well region 324 of the drift region 304 may be provided that is registered with the transition region 306_{T}. The doped well region 324 may comprise a doping type that is the same as that of the well region 312A and opposite that of the drift region 304. In this regard, the doped well region 324 may be configured to shield portions of the gate contact 318 that extend across the transition region 306_{T}. However, in this layout, the semiconductor device 300 may be vulnerable to transient voltage events that may occur during operation and/or device testing. In particular, a high rate of voltage change over time (dV/dt) can be induced during switching events. The high dV/dt may cause dielectric breakdown or other defects and damage in the gate insulating layer 316 that is in the transition region 306_{T}.

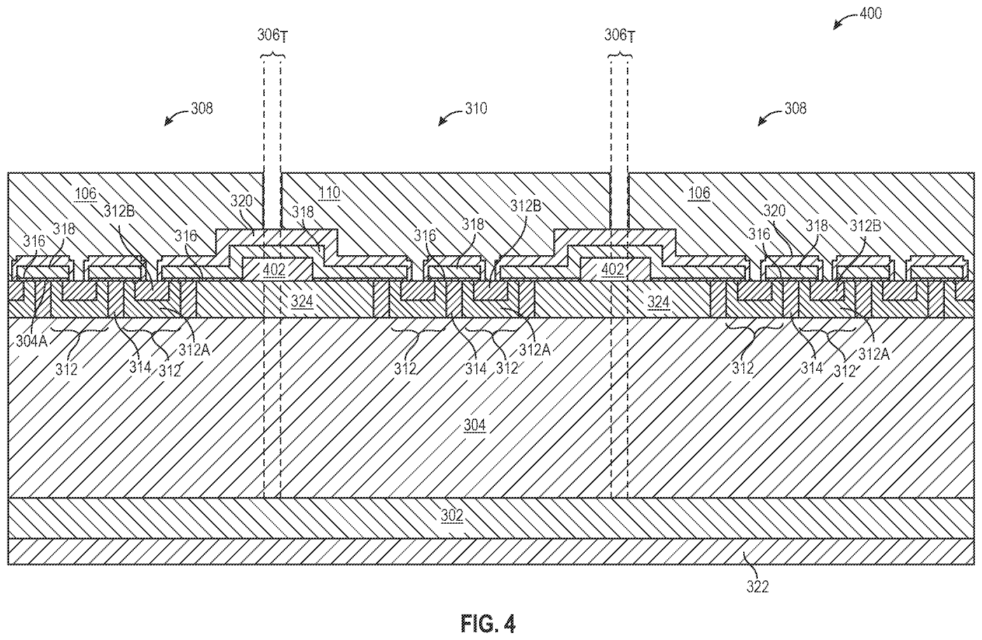

FIG. 4 illustrates a cross-sectional view of a portion of a first semiconductor device 400 that is similar to the semiconductor device 300 of FIG. 3 and further includes protection structures arranged in the transition region 306_{T} for shielding the gate insulating layer 316 from transient voltage events, defects, and other associated damage. An insulating layer 402 is provided on the top surface 304A of the drift region 304 to provide protection for the gate insulating layer 316. The insulating layer 402 may further be provided on the top surface 304A of the drift region 304 in an area where the top surface 304A includes the doped well region 324. In certain embodiments, the insulating layer 402 may be formed on the drift region 304 before the gate insulating layer 316 and the gate contact 318 are formed, thereby arranging the insulating layer 402 between the gate contact 318 and the drift region 304 in the transition region 306_{T}. Additionally, the insulating layer 402 prevents the thin gate insulating layer 316 from entirely covering the top surface 304A of the drift region 304 in the transition region 306_{T} such that at least a portion of the top surface 304A is devoid of the gate insulating layer 316 in the transition region 306_{T}. In certain embodiments, the insulating layer 402 may be provided on the top surface of the gate contact 318 and between the gate contact 318 and the drift region 304. Additionally, in some embodiments, the gate insulating layer 316 may not be provided between the insulating layer 402 and the gate contact 318 in the transition region 306_{T}, thereby reducing the overall presence of the gate insulating layer 316. In any of the above-described example embodiments, the insulating layer 402 provides a shield or barrier that reduces the impact of transient voltage events along the transition region 306_{T}, where the gate insulating layer 316 is most susceptible to damage. In particular, weak spots formed by the interface between the gate insulating layer 316 and the top surface 304A of the drift region 304 along the transition region 306_{T} are reduced.

In certain embodiments, the insulating layer 402 comprises a structure that has a higher breakdown voltage than a breakdown voltage of the gate insulating layer 316. For example, the breakdown voltage of the insulating layer 402 may be at least 1.5 times greater, or at least 2 times greater, or at least 3 times greater, or at least 5 times greater, or at least 10 times greater, or at least 50 times greater, or at least 100 times greater, or at least 200 times greater than the breakdown voltage of the gate insulating layer 316, or any range with endpoints defined by any of the preceding values. For example, the breakdown voltage of the insulating layer 402 may be in a range from 1.5 times greater to 200 times greater, or in a range from 1.5 times greater to 100 times greater, or in a range from 5 times greater to 100 times, or in a range from 5 times greater to 200 times greater than the breakdown voltage of the gate insulating layer 316. In a particular example, the insulating layer 402 comprises a breakdown voltage in a range from 650 volts (V) to 750 V while the gate insulating layer 316 comprises a breakdown voltage in a range from 40 V to 60 V.

In certain embodiments, the insulating layer 402 may comprise a different material that has a higher breakdown voltage than the material of the gate insulating layer 316. In such embodiments, the thicknesses of the insulating layer 402 and the gate insulating layer 316 may be the same or different, as long as the insulating layer 402 has the higher breakdown voltage. In other embodiments, the insulating layer 402 and the gate insulating layer 316 may comprise a same material and the higher breakdown voltage is achieved by providing the insulating layer 402 with a thickness or height from the drift region 304 that is thicker than a corresponding thickness or height of the gate insulating layer 316. For example, the thickness of the insulating layer 402 may be at least 1.5 times, or at least 2 times, or at least 3 times, or at least 100 times the thickness of the gate insulating layer 316, or in a range from 1.5 times to 50 times, or in a range from 1.5 times to 100 times, or in a range from 2 times to 50 times, or in a range from 2 times to 100 times the thickness of the gate insulating layer 316. In a particular example, the insulating layer 402 comprises a thickness in a range from 550 nanometers (nm) to 650 nm and the gate insulating layer 316 comprises a thickness in a range from 30 nm to 50 nm. For MOSFET applications, the gate insulating layer 316 may comprise a gate oxide and the insulating layer 402 may comprise a thicker field oxide layer as described above. In such embodiments, both the gate insulating layer 316 and the insulating layer 402 may comprise silicon dioxide, among other gate oxides used in MOSFET applications.

By having the protection structure provided by the insulating layer 402, the overall structure of the first semiconductor device 400 is more robust for handling transient voltage events, including one or more dV/dt events that may be induced during high speed switching. For example, a SiC MOSFET device with the insulating layer 402 of the present disclosure may thereby be configured to withstand or be rated for a dV/dt of at least 10 kilovolts per microsecond (kV/μs) without device failure. In still further embodiments, the SiC MOSFET device is configured to withstand a dV/dt of at least 30 kV/μs, or at least 50 kV/μs, or at least 100 kV/μs, or in a range from 10 kV/μs to 100 kV/μs, or in a range from 10 kV/μs to 200 kV/μs, or in a range from 50 kV/μs to 150 kV/μs, or in a range from 100 kV/μs to 200 kV/μs, or in any range with endpoints determined by any of the preceding values without device failure. In still further embodiments, the SiC MOSFET device is capable of withstanding any of the above dV/dt values for a single switching cycle to at least 1000 switching cycles or more. In any of the above-described embodiments, the exemplary SiC MOSFET may comprise a 4H-SiC MOSFET device.

In some instances, the material used to form the gate contacts (e.g., the gate contacts 318 in FIG. 3) is resistive or highly resistive. In a non-limiting nonexclusive embodiment, the material that is used to form the gate contacts is a p-type polysilicon. The higher resistivity of the p-type polysilicon can cause the potential across the gate contacts to vary based on the locations of the gate contacts with respect to an input for a gate signal. These potential differences may cause a propagation delay (e.g., resistance and capacitance (RC) delays) in the gate signal, which causes the transistors to turn on at different times (e.g., transistors M_{D} and Mₛₑₙₛₑ in FIGS. 2A and 2B). Generally, it is preferred to have the transistors, particularly the transistors in the sensor regions, turn on as a unit. When the transistors turn on as a unit, the transistors turn on at the same time (or at substantially the same time).

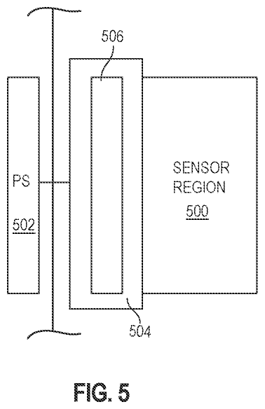

One technique that can be used to cause the transistors in the sensor regions to turn on as a unit is to reduce a resistance of the gate contact material. FIG. 5 illustrates a top view of a portion of a semiconductor device that reduces the resistance of the gate contact material according to embodiments of the present disclosure. A sensor region 500 (e.g., sensor region 310 in FIG. 3) is electrically connected to a power source (PS) 502 through a gate contact 504 (e.g., gate contact 318 in the sensor region 310 of FIG. 4). A conductive segment 506 is disposed over the gate contact 504. In some embodiments, the conductive segment 506 is in direct contact with the gate contact 504. The conductive segment 506 reduces the resistivity of the material in the gate contact 504, which in turn reduces or eliminates the propagation delays (e.g., signal-to-gate propagation delays) to the transistors. For example, the conductive segment 506 can average out the propagation delays to reduce the overall delay.

The source contacts (e.g., source contacts 106), the sensor contacts (e.g., sensor contacts 110), the drain contacts (e.g., drain contacts 322), and the conductive segments 506 can all be made of the same conductive material or at least one may be made of a different conductive material. Additionally, the source contacts, the sensor contacts, the drain contacts, and the conductive segments 506 may embody one or more layers of a conductive material or conductive materials. One example of a conductive material is metal.

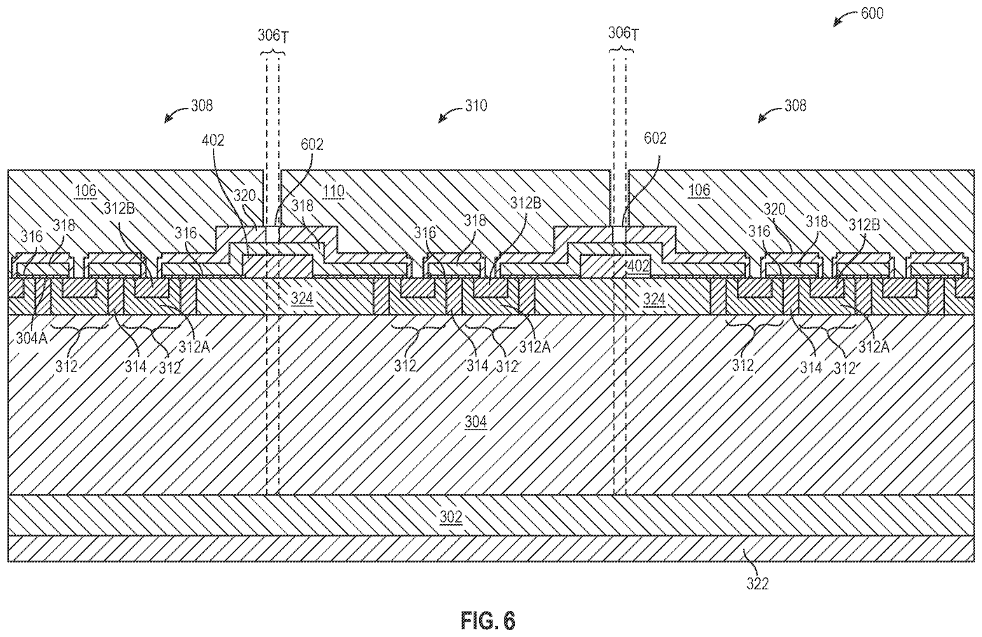

FIG. 6 illustrates a cross-sectional view of a portion of a second semiconductor device 600 that is similar to the first semiconductor device 400 of FIG. 4 and includes conductive segments 602 formed over gate contacts 318 according to embodiments of the present disclosure. A conductive segment 602 is disposed over the gate contact 318 within a respective transition region 306_{T}. In the illustrated embodiment, the conductive segment 602 is in direct contact with the gate contact 318.

The conductive segment 602 is disposed in the transition region 306_{T} between the source contact 106 and the sensor contact 110. The conductive segment 602 does not directly contact the source contact 106 and the sensor contact 110. The conductive segment 602 is disposed between the portions of the passivation layer 320 in the transition region 306_{T}. The passivation layer 320 is not disposed on the conductive segment 602 in the transition region 306_{T}.

The conductive segments 602 reduce the resistivity of the material that is used to form the gate contacts 318. As described earlier, reducing the resistivity can reduce or eliminate the propagation delays in the gate signals applied to the gate contacts 318 of the transistors in the device region 308 and the sensor region 310. In a non-limiting nonexclusive example, a metal is used to form the conductive segments 602 and polysilicon is used to form the gate contacts 318.

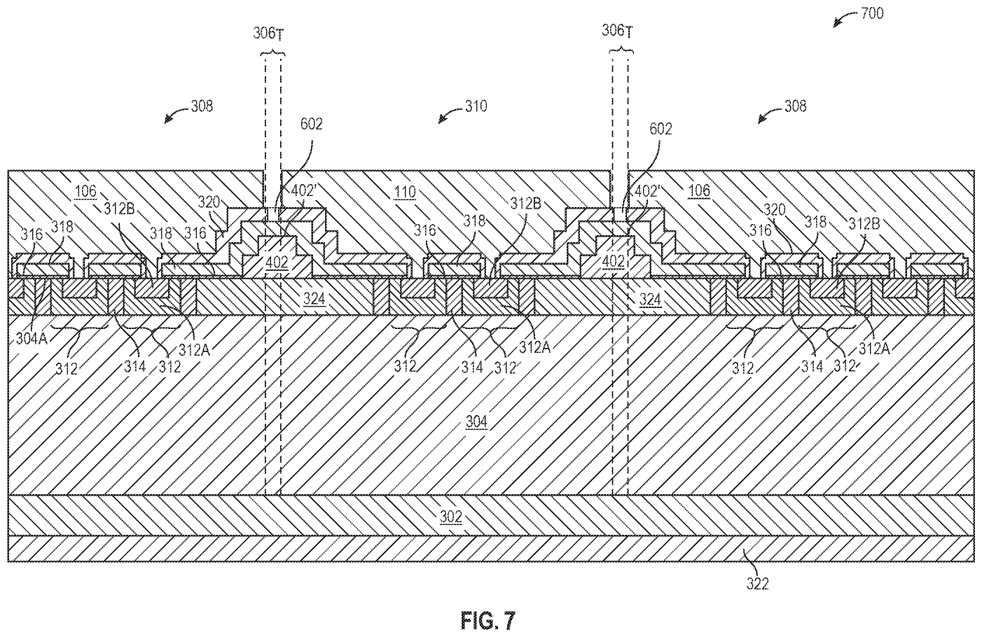

FIG. 7 illustrates a cross-sectional view of a portion of a third semiconductor device 700 that is similar to the first semiconductor device 400 of FIG. 4 and the second semiconductor device 600 of FIG. 6 and includes an insulating layer 402 that forms a nonplanar shape according to embodiments of the present disclosure. In FIG. 7, a thicker portion 402′ of the insulating layer 402 is formed along a center of the insulating layer 402 to form one or more nonplanar surfaces thereof that are opposite the drift region 304. In this manner, an increased amount of the protection structure provided by the insulating layer 402 may be formed in the transition region 306_{T} without increasing a lateral footprint of the insulating layer 402 with respect to the drift region 304. While the increased thickness portion 402′ of the insulating layer 402 is illustrated at the center of the insulating layer 402, the increased thickness portion 402′ may be arranged closer to either the sensor region 310 or the device region 308 depending on the embodiment. In further embodiments, the insulating layer 402 may be formed with multiple increased thickness portions 402′. In FIG. 7, the increased thickness portion 402′ forms a stepped profile for the insulating layer 402. In other embodiments, the increased thickness portion 402′ may form a peak that is sloped in one or more of a linear and/or curved manner toward the lateral edges of the insulating layer 402.

The third semiconductor device 700 also includes the conductive segments 602 in the transition regions 306_{T}. As described earlier, the conductive segments 602 are disposed between (and do not contact) the source contacts 106 and the sensor contacts 110. The conductive segments 602 are disposed between the portions of the passivation layer 320 in the transition regions 306_{T} and are not covered by the passivation layer 320.

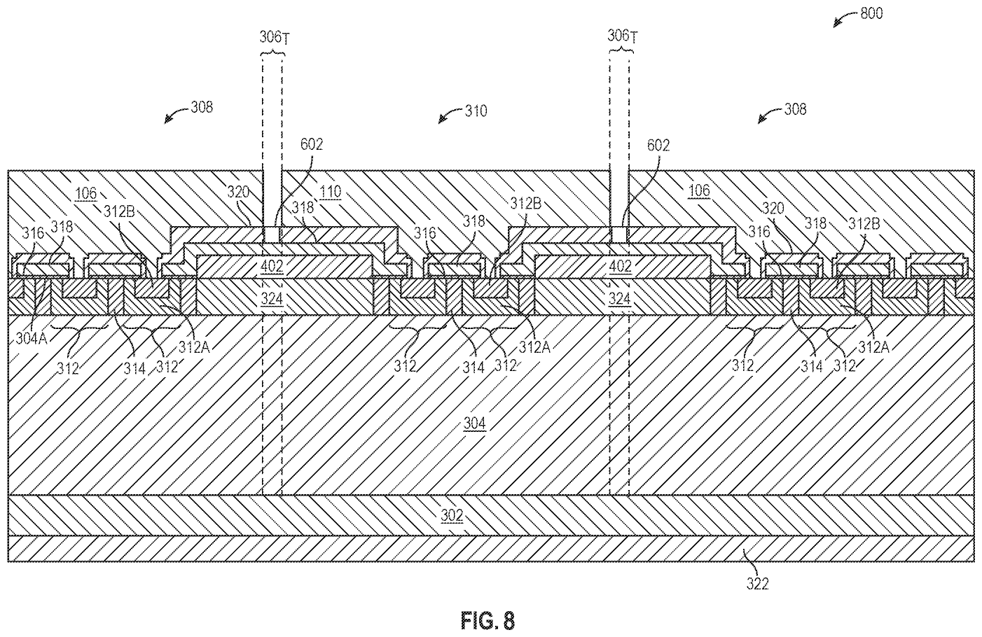

FIG. 8 illustrates a cross-sectional view of a portion of a fourth semiconductor device 800 that is similar to the first semiconductor device 400 of FIG. 4 and the second semiconductor device 600 of FIG. 6 and includes an insulating layer 402 that is formed to cover a larger portion of a top surface of the drift region 304 according to embodiments of the present disclosure. As illustrated, the insulating layer 402 may be formed with a lateral width that is close to or the same as a lateral width of the doped well region 324 of the drift region 304. In this manner, the amount of material for the gate insulating layer 316 may be further reduced in areas of the fourth semiconductor device 800 that are along the transition region 306_{T}. In embodiments where the gate insulating layer 316 is not formed over the insulating layer 402, the gate insulating layer 316 is therefore spaced farther away from the transition region 306_{T} to further reduce the impact from transient voltage events. While the insulating layer 402 is shown with a same lateral width as that of the doped well region 324 in FIG. 8, the insulating layer 402 may be formed with an increased width that is less than the width of the doped well region 324. For example, the insulating layer 402 may be formed with a width that is at least 50%, or at least 75%, or at least 90%, or in a range from 50% to 100% of the width of the doped well region 324 in various embodiments.

The fourth semiconductor device 800 further includes the conductive segments 602 in the transition regions 306_{T}. As described earlier, the conductive segments 602 are disposed between (and do not contact) the source contacts 106 and the sensor contacts 110. The conductive segments 602 are disposed between the portions of the passivation layer 320 in the transition regions 306_{T} and are not covered by the passivation layer 320.

As shown in FIG. 4, each doped well region 324 is formed under the gate contact 318 and extends across a respective transition region 306_{T} and into portions of the device region 308 and the sensor region 310 that are immediately adjacent to (e.g., abut) the respective transition region 306_{T}. In some situations, such as when a transistor in the device region 308 switches from an off state to an on state, current in the device region 308 can propagate into an adjacent sensor region 310. The displaced current in the sensor region 310 may cause a few transistors in the sensor region 310 (e.g., current sensors) to switch to an on state, in some cases even before the transistors in the device region 308 switch to the on state. When transistors in the sensor region 310 switch to the on state based on the displaced current, the ratio of the current flow that was set at a particular ratio (e.g., a ratio of 1:250) for the semiconductor device may not remain the same.

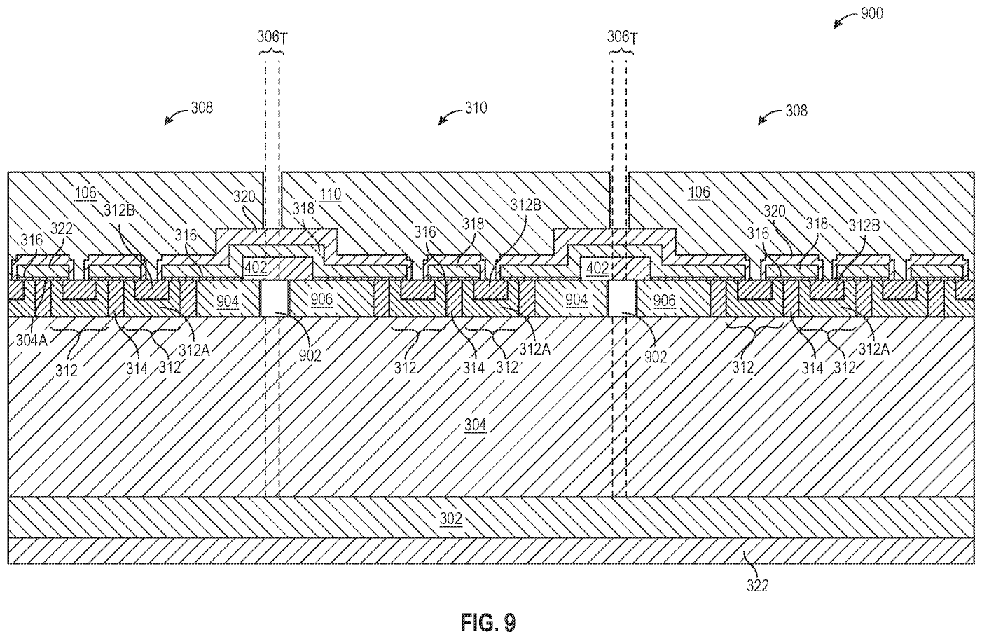

One technique that can be used to reduce or eliminate current displacement into the sensor region 310 is to isolate a doped well region in the device region 308 from a doped well region in the sensor region 310. FIG. 9 illustrates a cross-sectional view of a portion of a fifth semiconductor device 900 that is similar to the first semiconductor device 400 of FIG. 4 and includes an isolation region 902 positioned between an isolated well region 904 in the device region 308 and an isolated well region 906 in the sensor region 310 according to embodiments of the present disclosure. The isolation region 902 is formed in a portion of the drift region 304 in the transition region 306_{T} to isolate the isolated well region 904 in a portion of the drift region 304 in the device region 308 from the isolated well region 906 in a portion of the drift region 304 in the sensor region 310. Essentially, the isolation region 902 separates the doped well region 324 in FIG. 4 into the two isolated well regions 904, 906. The isolation region 902 is positioned with respect to the transition region 306_{T} (e.g., registered with the transition region 306_{T}).

In a non-limiting nonexclusive embodiment, the isolation regions 902 and the JFET regions 314 are associated with the same or substantially similar electric fields such that the isolation regions 902 form a current mirror of the JFET regions 314. As such, the isolation regions 902 are formed of the same material and with the same doping type and doping concentration as the JFET regions 314. Additionally or alternatively, the isolation regions 902 have a width or area that equals or substantially equals a width or area of the JFET regions 314.

The isolated well region 904 in the device region 308 is formed between a JFET region 314 and a first edge or side of the isolation region 902. At least a portion of the isolated well region 904 is also formed under the gate contact 318. Similarly, the isolated well region 906 in the sensor region 310 is formed between another JFET region 314 and a second edge of the isolation region 902 that is opposite the first edge of the isolation region 902. Like the isolated well region 904, at least a portion of the isolated well region 906 is formed under the gate contact 318. In the illustrated embodiment, at least a portion of the isolated well region 904 and at least a portion of the isolated well region 906 are formed under portions of the insulating layer 402.

The isolation region 902 prevents current in the device region 308 from propagating into an adjacent sensor region 310. The transistor(s) in the sensor region 310 will remain in the off state while the transistor(s) in the device region 308 transition to the on state. Accordingly, the ratio of the current flow that was set at a particular ratio (e.g., a ratio of 1:250) for the semiconductor device is maintained during switching operations.

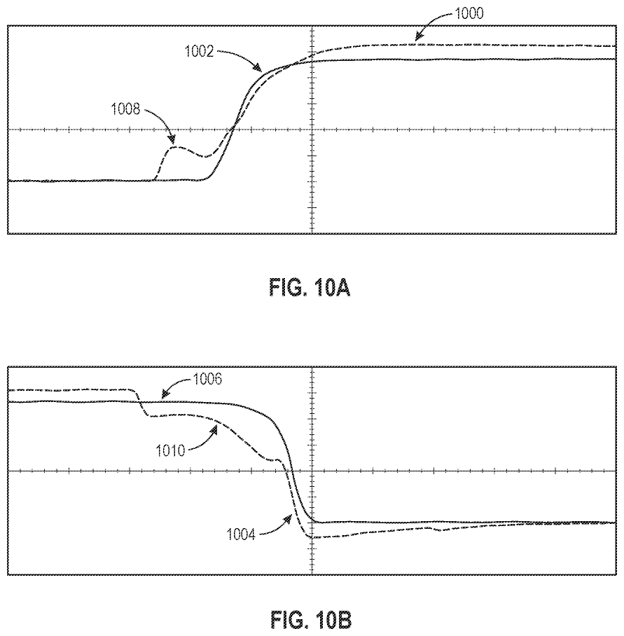

FIGS. 10A-10B illustrate waveforms for a device MOSFET and a sensing MOSFET during switching operations. In particular, waveform 1000 in FIG. 10A represents the current as the sensing MOSFET (e.g., Mₛₑₙₛₑ in FIG. 2A and FIG. 2B) switches to an on state, and the waveform 1002 represents the current as the device MOSFET (e.g., M_{D} in FIG. 2A and FIG. 2B) switches to the on state. The sensing MOSFET is implemented as a current sensor, and the waveform 1000 represents the current as the current sensor switches to the on state.

Waveforms 1004, 1006 in FIG. 10B depict the current as the current sensor and the device MOSFET, respectively, switch to an off state. As shown in FIGS. 10A and 10B, the waveforms 1000 and 1004 for the current sensor follow the waveforms 1002 and 1006, respectively, for the device MOSFET except in variation areas 1008, 1010. The variation area 1008 represents a time period when a few current sensors switch to an on state before the remaining current sensors switch to the on state. The variation area 1010 represents a time period when a few current sensors switch to an off state before the remaining current sensors switch to the off state.

When the slope of the waveforms 1000, 1004 are as shown in variation areas 1008, 1010, the current in the device MOSFET is not detectable by the current sensor. When the waveforms 1000, 1004 follow the waveforms 1002, 1006, respectively, the current sensor can be used to detect changes or events in the device MOSFET when or as the events occur. In a non-limiting nonexclusive example, the current sensor may be used to detect short circuit events in the device MOSFET. In another non-limiting nonexclusive example, current in the device MOSFET is monitored continuously or at select times for low Rds_on conditions in solid state relays. Additionally or alternatively, the current sensor may be used for cycle-by-cycle control, where the current sensor may eliminate hall effect current sensors to save cost and die area (e.g., in an inverter circuit).

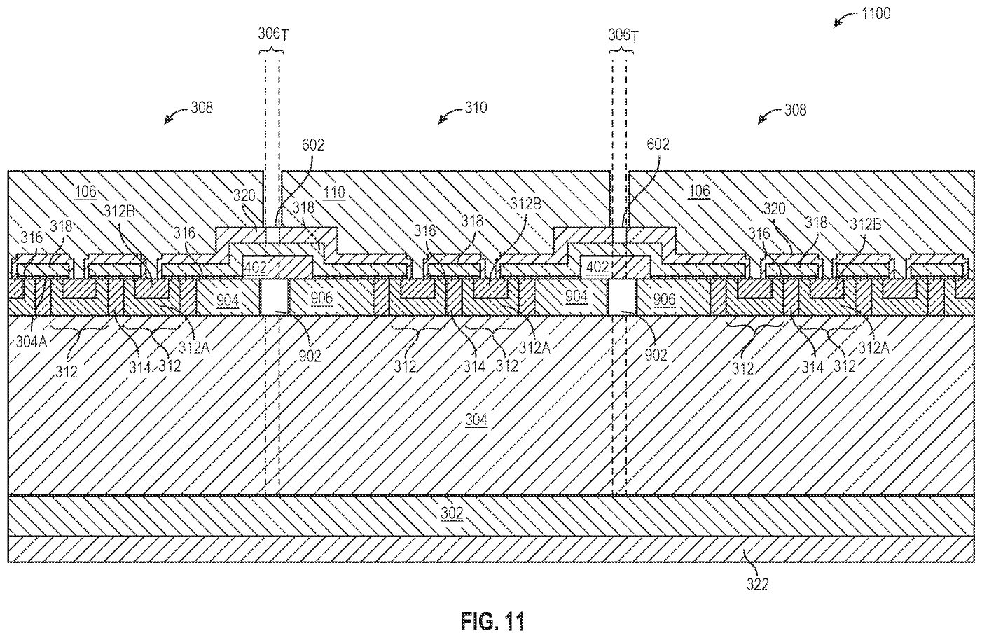

FIG. 11 illustrates a cross-sectional view of a portion of a sixth semiconductor device 1100 that is similar to the fifth semiconductor device 900 of FIG. 9 and that is operable to detect one or more events in one or more device MOSFETs according to embodiments of the present disclosure. The sixth semiconductor device 1100 includes the conductive segments 602 formed on the gate contacts 318 and the isolation regions 902 formed in the transition region 306_{T} under the gate contacts 318. As described previously, the isolation regions 902 prevent current in a respective device region 308 (e.g., one or more device MOSFETs) from propagating into an adjacent sensor region 310. The isolation regions 902 reduce or eliminate the variation areas in the current waveforms of the current sensor (e.g., variation areas 1008, 1010) so that the current waveforms follow (or substantially follow) the current waveforms of one or more device MOSFETs (e.g., the device regions 308). The conductive segments 602 reduce the resistivity of the material in the gate contacts 318 and enable the current sensors to switch to an on state at the same time (or at substantially the same time).

The combination of the isolation regions 902 to isolate the isolated well regions 904, 906 and the conductive segments 602 enable the sixth semiconductor device 1100 to detect events in the one or more device MOSFETs, such as short circuit events. In some on-chip sensors, such as on-chip current sensors, the time period for detecting current and/or events in the device MOSFETs is one or more microseconds. This allows the device MOSFET to be turned off or isolated to prevent the device MOSFET from being damaged. In one example embodiment, the sixth semiconductor device 1100 (e.g., a current sensor in the sixth semiconductor device 1100) can detect an event (e.g., a short circuit event) in less than a microsecond. In another example embodiment, the sixth semiconductor device 1100 (e.g., a current sensor in the sixth semiconductor device 1100) can detect an event, such as a short circuit event, in one to five microseconds or in less than ten microseconds. In yet another example embodiment, the sixth semiconductor device 1100 (e.g., a current sensor in the sixth semiconductor device 1100) can detect an event in tens of microseconds.

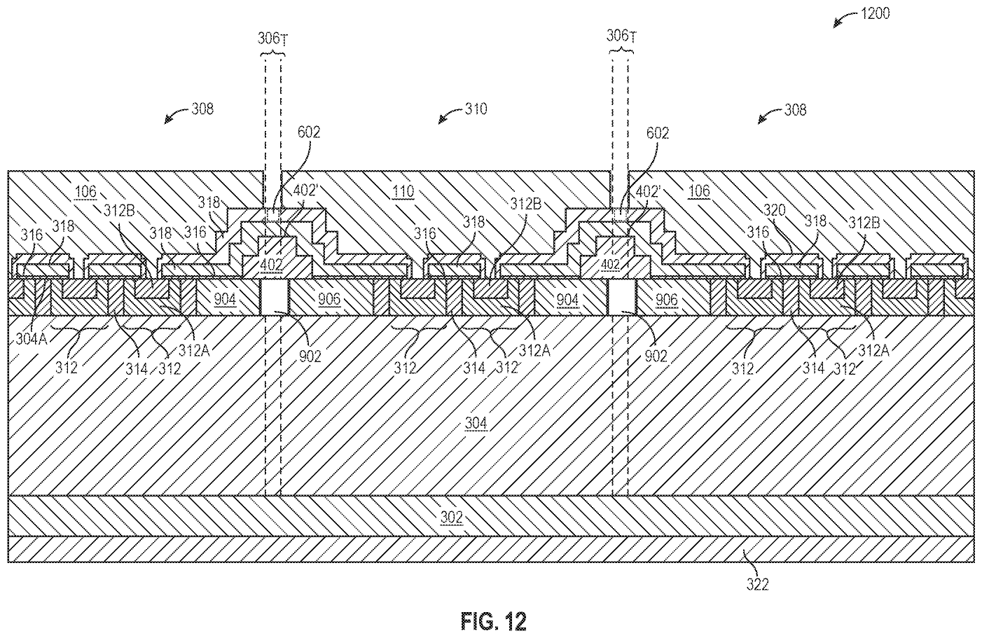

FIG. 12 illustrates a cross-sectional view of a portion of a seventh semiconductor device 1200 that is similar to the third semiconductor device 700 of FIG. 7 and to the fifth semiconductor device 900 of FIG. 9 and includes the isolation regions 902 and the insulating layer 402 that forms the nonplanar shape according to embodiments of the present disclosure. Similar to FIG. 7, the thicker portion 402′ of the insulating layer 402 is formed over the insulating layer 402 to form one or more nonplanar surfaces thereof that are opposite the drift region 304. The increased thickness portion 402′ can be formed in any shape or profile, such as in a stepped profile or in a peak that is sloped in one or more of a linear and/or curved manner toward the lateral edges of the insulating layer 402. Although the increased thickness portion 402′ of the insulating layer 402 is illustrated at the center of the insulating layer 402, the increased thickness portion 402′ may be arranged closer to either the sensor region 310 or the device region 308 depending on the embodiment. In further embodiments, the insulating layer 402 may be formed with multiple increased thickness portions 402′.

The seventh semiconductor device 1200 can further include the isolation regions 902 positioned between the isolated well regions 904, 906 in the device region 308 and in the sensor region 310, respectively. The isolation regions 902 are formed in the transition regions 306_{T} to separate or isolate the isolated well region 904 from the isolated well region 906. The isolation regions 902 can be formed of the same material and have the same doping type, doping concentration, and width as the JFET regions 314. In certain embodiments, the isolation regions 902 and the isolated well regions 904, 906 are omitted. In such embodiments, the doped well region 324 extends across a respective transition region 306_{T} and into portions of a respective device region 308 and a respective sensor region 310.

The seventh semiconductor device 1200 can optionally include the conductive segments 602 (shown in dashed lines). The conductive segments 602 are disposed between (and do not contact) the source contacts 106 and the sensor contacts 110. The conductive segments 602 are disposed between the portions of the passivation layer 320 in the transition regions 306_{T} and are not covered by the passivation layer 320.

As described earlier, the conductive segments 602 reduce the resistivity of the material that is used to form the gate contacts 318. The reduced resistivity can reduce or eliminate the propagation delays in the gate signals applied to the gate contacts 318 of the transistors in the sensor regions 310. Additionally, the combination of the isolation regions 902 to isolate the isolated well regions 904, 906 and the conductive segments 602 enable the seventh semiconductor device 1200 to detect events in the device MOSFETs, such as short circuit events.

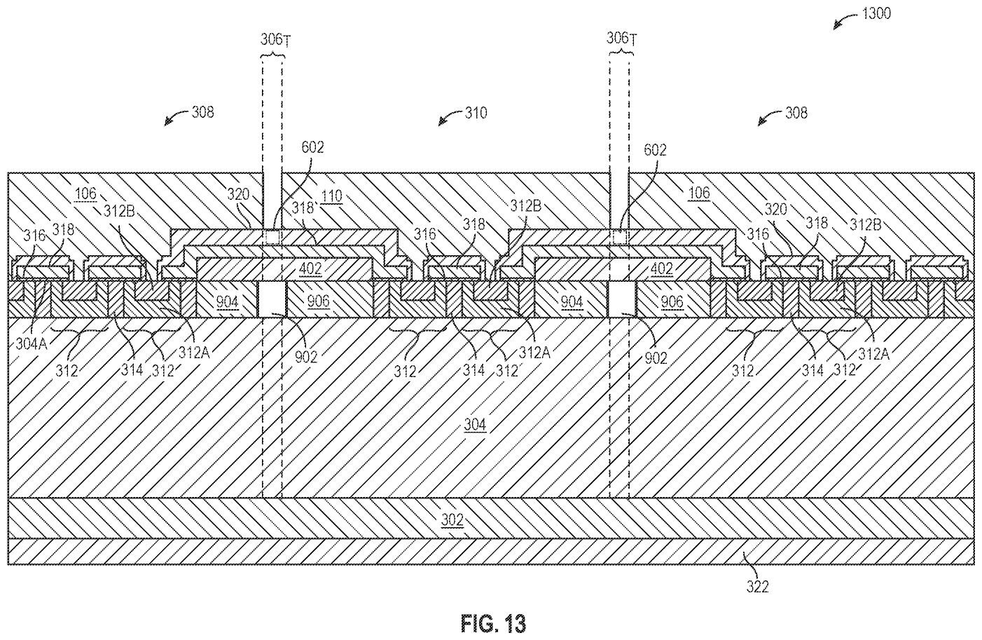

FIG. 13 illustrates a cross-sectional view of a portion of an eighth semiconductor device 1300 that is similar to the fourth semiconductor device 800 of FIG. 8 and to the fifth semiconductor device 900 of FIG. 9 and includes the isolation regions 902 and the insulating layer 402 that is formed to cover larger portions of the top surface of the drift region 304 according to embodiments of the present disclosure. As illustrated, the insulating layer 402 may be formed with a lateral width that is close to or the same as the lateral width of the doped well region 324 of the drift region 304. In this manner, the amount of material for the gate insulating layer 316 may be reduced in areas of the eighth semiconductor device 1300 that are along the transition region 306_{T}. In embodiments where the gate insulating layer 316 is not formed over the insulating layer 402, the gate insulating layer 316 is therefore spaced farther away from the transition region 306_{T} to further reduce the impact from transient voltage events.

While the insulating layer 402 is shown with a same lateral width as that of the combined isolation region 902 and isolated well regions 904, 906, the insulating layer 402 may be formed with an increased width that is less than the width of the doped well region 324. For example, the insulating layer 402 may be formed with a width that is at least 50%, or at least 75%, or at least 90%, or in a range from 50% to 100% of the width of the combined isolation region 902 and isolated well regions 904, 906 in various embodiments.

The eighth semiconductor device 1300 can further include the isolation regions 902 positioned between the isolated well region 904 in the device region 308 and the isolated well region 906 in the sensor region 310. The isolation regions 902 are formed in the transition regions 306_{T} to separate or isolate the isolated well region 904 from the isolated well region 906. The isolation regions 902 can be formed of the same material and have the same doping type, doping concentration, and width as the JFET regions 314. In certain embodiments, the isolation regions 902 and the isolated well regions 904, 906 are omitted. In such embodiments, the doped well region 324 extends across a respective transition region 306_{T} and into portions of a respective device region 308 and a respective sensor region 310.

The eighth semiconductor device 1300 can optionally include the conductive segments 602 (shown in dashed lines). The conductive segments 602 are disposed between (and do not contact) the source contacts 106 and the sensor contacts 110. The conductive segments 602 are disposed between the portions of the passivation layer 320 in the transition regions 306_{T} and are not covered by the passivation layer 320.

As described earlier, the conductive segments 602 reduce the resistivity of the material that is used to form the gate contacts 318. The reduced resistivity can reduce or eliminate the propagation delays in the gate signals applied to the gate contacts 318 of the transistors in the sensor regions 310. Additionally, the combination of the isolation regions 902 to isolate the isolated well regions 904, 906 and the conductive segments 602 enable the eighth semiconductor device 1300 to detect events in the device MOSFETs, such as short circuit events.

Delays between current sensors and delay from a gate signal are two characteristics that impact the performance of a current sensor. The delays between current sensors represent a delay between a time when a first current sensor in the sensor region transitions to an on state (turns on) and when the last current sensor in the sensor region turns on. The delay from the gate signal represents a delay between a time when the gate signal is applied to a sensor contact and a time when a current sensor in the sensor region turns on. The layout of a sensor region within an active region can have an impact on these types of delays.

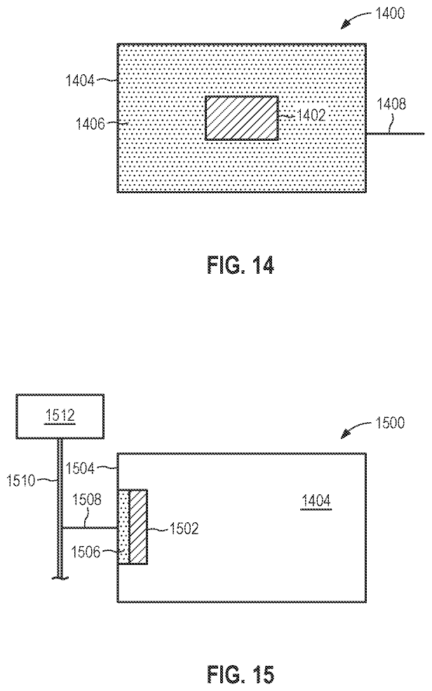

FIG. 14 illustrates an example first layout 1400 for the sensor region 1402. The sensor region 1402 is arranged in a rectangular shape and positioned in the center of the rectangular-shaped active region 1404. A gate contact 1406 surrounds the sensor region 1402. When a gate signal is applied to the gate contact 1406 via the gate signal line 1408, the current sensors in the sensor region 1402 receive the gate signal from all directions. Accordingly, the current sensors turn on at different times because the gate signal propagates to the current sensors at different times. The delays between current sensors and the delay from the gate signal can both adversely impact the performance of the sensor region 1402.

FIGS. 15-17 depict example layouts that may reduce the delays between current sensors and/or the delay from the gate signal. Device regions (not shown in FIGS. 15-17) and the sensor regions shown in FIGS. 15-17 can be implemented as any one of the embodiments shown in FIGS. 6-9 and 11-13.

FIG. 15 illustrates an example second layout 1500 for a sensor region 1502 according to embodiments of the disclosure. In the second layout 1500, the sensor region 1502 is arranged in a stripe or rectangular shape and positioned along the left edge 1504 of the active region 1404. A gate contact 1506 is arranged in a stripe or rectangular shape and positioned between the sensor region 1502 and the left edge 1504 of the active region 1404. A gate signal line 1508 is electrically connected to the gate contact 1506 and is used to apply a gate signal to the current sensors in the sensor region 1502.

A gate conductor 1510 is routed along the left edge 1504 of the active region 1404. The gate conductor 1510 electrically connects a contact pad 1512 to the gate signal line 1508. The contact pad 1512 is operable to receive a supply signal that is used to activate or turn on the current sensors in the sensor region 1502. The supply signal propagates on the gate conductor 1510 and a gate signal is applied to the gate contact 1506 via the gate signal line 1508. When the gate signal is applied to the gate contact 1506, the current sensors in the sensor region 1502 turn on at the same time, or at substantially the same time. The current sensors in the sensor region 1502 turn on at the same (or substantially the same) time because the gate signal propagates to the current sensors at substantially the same time. The current sensors in the sensor region 1502 are located at equal distances (or at substantially equal distances) from the gate contact 1506. The delays between current sensors and/or the delay from the gate signal are reduced or minimized, which improves the performance of the sensor region 1502.

Other embodiments are not limited to the shape, size, and/or position of the sensor region 1502, the gate contact 1506, and/or the gate conductor 1510. In a non-limiting example, the sensor region 1502 may be positioned along the top edge of the active region 1404, and the gate contact 1506 can be between the sensor region 1502 and the top edge of the active region 1404. In such embodiments, the gate conductor 1510 can be routed along the top edge of the active region 1404. Additionally, the active region 1404 may have a shape that is different from the rectangular shape shown in FIG. 15.

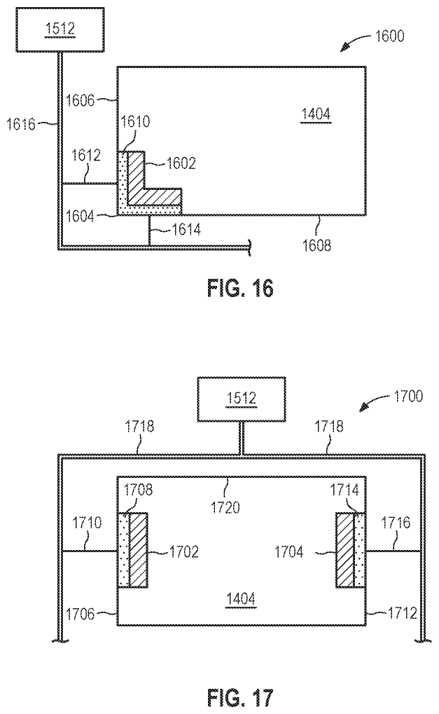

FIG. 16 illustrates an example third layout 1600 for a sensor region 1602 according to embodiments of the disclosure. The sensor region 1602 is arranged in an “L” shape and positioned near a lower left corner 1604 and along a left edge 1606 and a bottom edge 1608 of the active region 1404. A gate contact 1610 is arranged in an “L” shape and positioned between the sensor region 1602, the left edge 1606, and the bottom edge 1608 of the active region 1404. A first gate signal line 1612 is electrically connected to the gate contact 1610 at the left edge 1606, and a second gate signal line 1614 is electrically connected to the gate contact 1610 at the bottom edge 1608. The first gate signal line 1612 and the second gate signal line 1614 are used to apply a gate signal to the current sensors in the sensor region 1602.

A gate conductor 1616 is routed along the left edge 1606 and the bottom edge 1608 of the active region 1404. The gate conductor 1616 electrically connects the contact pad 1512 to the first gate signal line 1612 and to the second gate signal line 1614. As described previously, the contact pad 1512 is operable to receive a supply signal that is used to turn on the current sensors in the sensor region 1602. The supply signal propagates on the gate conductor 1616 and a gate signal is applied to the gate contact 1610 via the first gate signal line 1612 and the second gate signal line 1614. When the gate signal is applied to the gate contact 1610, the current sensors in the sensor region 1602 turn on at the same time, or at substantially the same time, because the gate signal propagates to the current sensors at substantially the same time. The current sensors in the sensor region 1602 are located at equal distances (or at substantially equal distances) from the gate contact 1610. The delays between current sensors and/or the delay from the gate signal are reduced or minimized, which improves the performance of the sensor region 1602.

Other embodiments are not limited to the shape, size, and/or position of the sensor region 1602, the gate contact 1610, and/or the gate conductor 1616. In a non-limiting example, the sensor region 1602 may be positioned near an upper corner of the active region along the top edge and the right edge of the active region 1404. The gate contact 1610 can be between the sensor region 1602, the top edge, and the right edge of the active region 1404. The gate conductor 1616 can be routed along the top edge and the right edge of the active region 1404. Additionally, the active region 1404 may have a shape that is different from the rectangular shape shown in FIG. 16.

FIG. 17 illustrates an example fourth layout 1700 for a first sensor region 1702 and a second sensor region 1704 according to embodiments of the disclosure. The first sensor region 1702 is arranged in a stripe or rectangular shape and positioned along the left edge 1706 of the active region 1404. A first gate contact 1708 is arranged in a stripe or rectangular shape and positioned between the first sensor region 1702 and the left edge 1706 of the active region 1404. A first gate signal line 1710 is electrically connected to the first gate contact 1708 and is used to apply a gate signal to the current sensors in the first sensor region 1702.

The second sensor region 1704 is arranged in a stripe or rectangular shape and positioned along the right edge 1712 of the active region 1404. A second gate contact 1714 is arranged in a stripe or rectangular shape and positioned between the second sensor region 1704 and the right edge 1712 of the active region 1404. A second gate signal line 1716 is electrically connected to the second gate contact 1714 and is used to apply a gate signal to the current sensors in the second sensor region 1704.

A gate conductor 1718 is routed along the top edge 1720, the left edge 1706, and the right edge 1712 of the active region 1404. The gate conductor 1718 electrically connects the contact pad 1512 to the first gate signal line 1710 and to the second gate signal line 1716. As described previously, the contact pad 1512 is operable to receive a supply signal that is used to turn on the current sensors in the first sensor region 1702 and in the second sensor region 1704. The supply signal propagates on the gate conductor 1718 and a gate signal is applied to the first gate contact 1708 via the first gate signal line 1710 and to the second gate contact 1714 via the second gate signal line 1716.

When the gate signal is applied to the first gate contact 1708 and to the second gate contact 1714, the current sensors in the first sensor region 1702 and in the second sensor region 1704, respectively, turn on at the same time, or at substantially the same time, because the gate signal propagates to the current sensors at substantially the same time. The current sensors in the first sensor region 1702 are located at equal distances (or at substantially equal distances) from the first gate contact 1708. Similarly, the current sensors in the second sensor region 1704 are located at equal distances (or at substantially equal distances) from the second gate contact 1714. Thus, the delays between current sensors and/or the delay from the gate signal are reduced or minimized, which improves the performance of the sensor region 1602.

Other embodiments are not limited to the shapes, sizes, and/or positions of the first sensor region 1702, the first gate contact 1708, the second sensor region 1704, and the second gate contact 1714, and/or the gate conductor 1718. In a non-limiting example, the first sensor region 1702 can be positioned along the top edge 1720 of the active region 1404, the second sensor region 1704 along the bottom edge of the active region 1404, the first gate contact 1708 between the first sensor region 1702 and the top edge 1720, and the second gate contact 1714 between the bottom edge and the second sensor region 1704. In such embodiments, the gate conductor 1718 can be routed along the top edge and the bottom edge of the active region 1404. Additionally, the active region 1404 may have a shape that is different from the rectangular shape shown in FIG. 17.

FIGS. 15-17 depict example sensor region shapes and sizes, gate contact shapes and sizes, gate conductors, and layouts that improve the performance of a sensor region. Other embodiments are not limited to these layouts, to the shape and/or the size of the illustrated sensor regions and gate contacts, or to the routing and shapes of the gate conductors. Any layout that positions the current sensors in one or more sensor regions at equal distances (or at substantially equal distances) from a respective gate contact that is electrically connected to a respective sensor region can be used. A layout for one or more sensor regions can depend on a several factors, including, but not limited to, a number of sensor regions, a shape of the sensor region(s), a shape of the gate contact(s), and the routing of one or more gate conductors.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A vertical semiconductor device comprising:
a drift region;
a device region that comprises a first portion of the drift region;
a sensor region that comprises a second portion of the drift region; and
a transition region between the device region and the sensor region, the transition region comprising:
a gate contact; and
a conductive segment on and in direct contact with the gate contact.

2. The vertical semiconductor device of claim 1, further comprising:
an insulating layer between the gate contact and the drift region; and
a gate insulating layer between the gate contact and the drift region.

3. The vertical semiconductor device of claim 2, wherein a thickness of the insulating layer is at least 1.5 times greater than a thickness of the gate insulating layer.

4. The vertical semiconductor device of claim 2, wherein a thickness of the insulating layer is in a range from 1.5 times greater to 100 times greater than a thickness of the gate insulating layer.

5. The vertical semiconductor device of claim 2, wherein a portion of the insulating layer has a thickness that is greater than thicknesses of other portions of the insulating layer.

6. The vertical semiconductor device of claim 1, wherein the sensor region comprises one or more current sensors.

7. The vertical semiconductor device of claim 1, wherein the first portion of the drift region is electrically connected between a first contact and a second contact and the second portion of the drift region is electrically connected between the first contact and a sensor contact.

8. The vertical semiconductor device of claim 7, wherein the vertical semiconductor device comprises a metal-oxide-semiconductor field-effect transistor (MOSFET), and the first contact is a drain contact and the second contact is a source contact.

9. The vertical semiconductor device of claim 1, further comprising:
a first isolated well region under the gate contact in the first portion of the drift region;
a second isolated well region under the gate contact in the second portion of the drift region; and
an isolation region under the gate contact in the transition region between the first and the second isolated well regions.

10. The vertical semiconductor device of claim 9, wherein the conductive segment and the isolation region that isolates the first and the second isolated well regions enable detection of a short circuit event in less than one microsecond of an occurrence of the short circuit event.

11. The vertical semiconductor device of claim 9, wherein the conductive segment and the isolation region that isolates the first isolated well region and the second isolated well region enable detection of a short circuit event within one microsecond to five microseconds of an occurrence of the short circuit event.

12. The vertical semiconductor device of claim 1, wherein:
the device region and the sensor region reside in an active region of the vertical semiconductor device;
the sensor region is arranged in a stripe shape and positioned along an edge of the active region;
the sensor region includes one or more current sensors; and
each current sensor in the sensor region is at an equal distance from a gate contact that is electrically connected to the one or more current sensors in the sensor region.

13. The vertical semiconductor device of claim 1, wherein:
the device region and the sensor region reside in an active region of the vertical semiconductor device;
the sensor region is arranged in an “L” shape and a lower corner of the sensor region is positioned near a corner of the active region;
the sensor region includes one or more current sensors; and
each current sensor in the sensor region is at an equal distance from a gate contact that is electrically connected to the one or more current sensors in the sensor region.

14. A vertical semiconductor device comprising:
a drift region;
a device region that comprises a first portion of the drift region;
a sensor region that comprises a second portion of the drift region;
a transition region between the device region and the sensor region, the transition region comprising:
a gate contact over the drift region; and
an isolation region in the drift region.

15. The vertical semiconductor device of claim 14, further comprising a conductive segment directly on the gate contact in the transition region.

16. The vertical semiconductor device of claim 15, wherein the conductive segment and the isolation region enable detection of a short circuit event in less than one microsecond of an occurrence of the short circuit event.

17. The vertical semiconductor device of claim 15, wherein the conductive segment and the isolation region enable detection of a short circuit event within one to five microseconds of an occurrence of the short circuit event.

18. The vertical semiconductor device of claim 14, wherein:
the first portion of the drift region is in the device region;
the second portion of the drift region is in the sensor region;
the isolation region is an n-type isolation region;
the first isolated well region is a first p-well region; and
the second isolated well region is a second p-well region.

19. The vertical semiconductor device of claim 14, further comprising an insulating layer between the gate contact and the drift region.

20. The vertical semiconductor device of claim 19, wherein a portion of the insulating layer has a thickness that is greater than thicknesses of other portions of the insulating layer.

21. The vertical semiconductor device of claim 14, wherein:
the sensor region forms a current sensor; and
the vertical semiconductor device comprises a metal-oxide-semiconductor field-effect transistor (MOSFET) with the first portion of the drift region electrically connected between a drain contact and a source contact and the second portion of the drift region electrically connected between the drain contact and a sensor contact.

22. The vertical semiconductor device of claim 14, wherein:
the device region and the sensor region reside in an active region of the vertical semiconductor device;
the sensor region is arranged in a stripe shape and positioned along an edge of the active region;
the sensor region includes one or more current sensors; and
each current sensor in the sensor region is at an equal distance from a gate contact that is electrically connected to the one or more current sensors in the sensor region.

23. A vertical silicon carbide (SiC) device comprising:
a device region;
a sensor region; and
a transition region between the device region and the sensor region, wherein the vertical SiC device is operable to detect a short circuit event in one microsecond to three microseconds.

24. The vertical SiC device of claim 23, further comprising:
a conductive segment on a gate contact; and
an isolation region under the gate contact and formed in a drift region.

25. The vertical SiC device of claim 24, further comprising:
a well region formed in the drift region adjacent the isolation region; and
a junction field-effect transistor (JFET) region formed in the drift region adjacent the well region, wherein the isolation region is a current mirror of the JFET region.

26. The vertical SiC device of claim 23, wherein:
the device region and the sensor region reside in an active region of the vertical SiC device;
the sensor region is arranged in a stripe shape and positioned along an edge of the active region;
the sensor region includes one or more sensors; and
each sensor in the sensor region is at an equal distance from a gate contact that is electrically connected to the one or more sensors in the sensor region.

27. The vertical SiC device of claim 23, wherein:
the device region and the sensor region reside in an active region of the vertical SiC device;
the sensor region is arranged in an “L” shape and a lower corner of the sensor region is positioned near a corner of the active region;
the sensor region includes one or more sensors; and
each sensor in the sensor region is at an equal distance from a gate contact that is electrically connected to the one or more sensors in the sensor region.

28. The vertical SiC device of claim 23, wherein:
the device region is a metal-oxide-semiconductor field-effect transistor (MOSFET) device region that includes one or more MOSFET transistors; and
the sensor region is a current sensor region that includes one or more current sensors.

29. A vertical semiconductor device, comprising:
a drift region;
a device region that comprises a first portion of the drift region; and
one or more sensor regions that each comprise a second portion of the drift region, wherein:
each sensor region includes one or more sensors; and
each sensor in a respective sensor region is at an equal distance from a respective gate contact that is electrically connected to the one or more sensors in the respective sensor region.

30. The vertical semiconductor device of claim 29, further comprising a transition region between the device region and a respective sensor region, the transition region comprising:
a gate contact over the drift region; and
an isolation region in the drift region.

31. The vertical semiconductor device of claim 29, further comprising a transition region between the device region and a respective sensor region, the transition region comprising:
a gate contact; and
a conductive segment on and in direct contact with the gate contact.

32. The vertical semiconductor device of claim 29, wherein:
the one or more sensor regions is a sensor region;
each sensor in the sensor region is at an equal distance from a gate contact that is electrically connected to the one or more sensors in the sensor region; and
the one or more sensors are one or more current sensors.

33. The vertical semiconductor device of claim 29, wherein:
the one or more sensor regions is a first sensor region and a second region;
the first sensor region includes one or more first sensors;
each first sensor in the first sensor region is at an equal distance from a first gate contact that is electrically connected to the one or more first sensors in the first sensor region;
the second sensor region includes one or more second sensors;
each second sensor in the second sensor region is at an equal distance from a second gate contact that is electrically connected to the one or more second sensors in the second sensor region;
the one or more first sensors are one or more first current sensors; and
the one or more second sensors are one or more second current sensors.
